(19) United States
(12) Patent Application Publication
(10) Pub. No.: US 2012/0133046 A1
(43) Pub. Date: May 31, 2012

(54) SEMICONDUCTOR STRUCTURE AND PROCESS THEREOF

(75) Inventors: Chun-Hsien Chien, Taipei County (TW); John H. Lau, Taipei City (TW); Hsiang-Hung Chang, Hsinchu County (TW); Huan-Chun Fu, Hsinchu City (TW); Tzu-Ying Kuo, Taipei City (TW); Wen-Li Tsai, Taichung County (TW)

(73) Assignee: INDUSTRIAL TECHNOLOGY RESEARCH INSTITUTE, Hsinchu (TW)

(21) Appl. No.: 13/037,372

(22) Filed: Mar. 1, 2011

(30) Foreign Application Priority Data
Nov. 25, 2010 (TW) 99140809

(51) Int. Cl. H01L 23/48; H01L 21/28

(52) U.S. Cl. 257/774; 438/637; 257/E23.011; 257/E21.158

(57) ABSTRACT

A semiconductor structure and a process thereof are provided. The semiconductor structure includes a semiconductor wafer having a first surface and a second surface opposite to the first surface, through silicon vias and a crack stopping slot. The through silicon vias are embedded in the semiconductor wafer and connected between the first surface and the second surface. The crack stopping slot is located in the periphery of the second surface of the semiconductor wafer. The depth of the crack stopping slot is less than or equal to the thickness of the semiconductor wafer. The process firstly provides a semiconductor wafer having through silicon vias. Then, the aforementioned crack stopping slot is formed at a back side of the semiconductor wafer opposite to the first surface. Next, the semiconductor wafer is thinned from the back side to expose a second end of each through silicon via.

### CROSS-REFERENCE TO RELATED APPLICATION

This application claims the priority benefit of Taiwan application serial no. 99140809, filed on Nov. 25, 2010. The entirety of the above-mentioned patent application is hereby incorporated by reference herein and made a part of this specification.

### TECHNICAL FIELD

The disclosure relates to a semiconductor structure having through silicon vias (TSVs) and a process thereof.

### BACKGROUND

In today's information society, electronic products tend to be light, thin, short, and small in design. Thus, a packaging technology such as stack-type semiconductor device packaging facilitating miniaturization is developed.

The stack-type semiconductor device packaging is to package a plurality of semiconductor devices in the same package structure by vertical stacking. In this way, the packaging density is increased and the package is miniaturized. Further, the signal transmission path between the semiconductor devices may be shortened by three-dimensional stacking, to increase the speed of signal transmission between the semiconductor devices. Moreover, the semiconductor devices with different functions can be combined in the same package.

In the current stack-type semiconductor device packaging, a plurality of TSVs is usually fabricated in a semiconductor device, to provide an electrical connection path in the vertical direction through the TSVs. The TSV is usually fabricated together with the device on a semiconductor wafer. Afterwards, the semiconductor wafer needs to be thinned from a back side thereof to expose a bonding end of the TSV.

However, the semiconductor wafer may produce a sharp edge when being thinned, so that wafer crack occurs to the semiconductor wafer in the subsequent process like backside metalization, which produces a crack extending from the edge to the central area of the semiconductor wafer. The crack will damage effective chip regions in the central area of the semiconductor wafer, and thus reduces the yield and throughput of the entire process.

### SUMMARY

A semiconductor structure is introduced herein, which comprises a semiconductor wafer, a plurality of TSVs, and a crack stopping slot. The semiconductor wafer has a first surface and a second surface opposite to the first surface. The TSVs are embedded in the semiconductor wafer, in which a first end of each TSV is connected to the first surface, and a second end of each TSV is connected to the second surface. The crack stopping slot is located in the periphery of the second surface of the semiconductor wafer, and a depth of the crack stopping slot is less than or equal to a thickness of the semiconductor wafer.

A semiconductor process is further introduced herein. A semiconductor wafer is provided, in which the semiconductor wafer has a first surface. The semiconductor wafer has a plurality of TSVs therein, and a first end of each TSV is connected to the first surface. A crack stopping slot is formed at a back side of the semiconductor wafer opposite to the first surface. The crack stopping slot is located in the periphery of the semiconductor wafer, and a depth of the crack stopping slot is less than or equal to a thickness of the semiconductor wafer. The semiconductor wafer is thinned from the back side to expose a second end of each TSV and a second surface of the semiconductor wafer.

Several exemplary embodiments accompanied with figures are described in detail below to further describe the disclosure in details.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the disclosure.

FIG. 1A is a schematic diagram illustrating a cross section of a semiconductor structure according to an embodiment of the disclosure.

FIG. 1B is a schematic diagram illustrating a cross section of a semiconductor structure according to another embodiment of the disclosure.

FIG. 2 is a schematic diagram illustrating a top view of the semiconductor structure in FIG. 1A or 1B.

FIG. 3 is schematic diagram illustrating a top view of a semiconductor structure according to another embodiment of the disclosure.

FIGS. 4 and 5 are respectively schematic diagrams illustrating two possible cross-sectional structures of a crack stopping slot in FIG. 1A or 1B.

FIGS. 6A to 6E are schematic diagrams illustrating cross sections of a process of the semiconductor structure in FIG. 1A.

### DETAILED DESCRIPTION

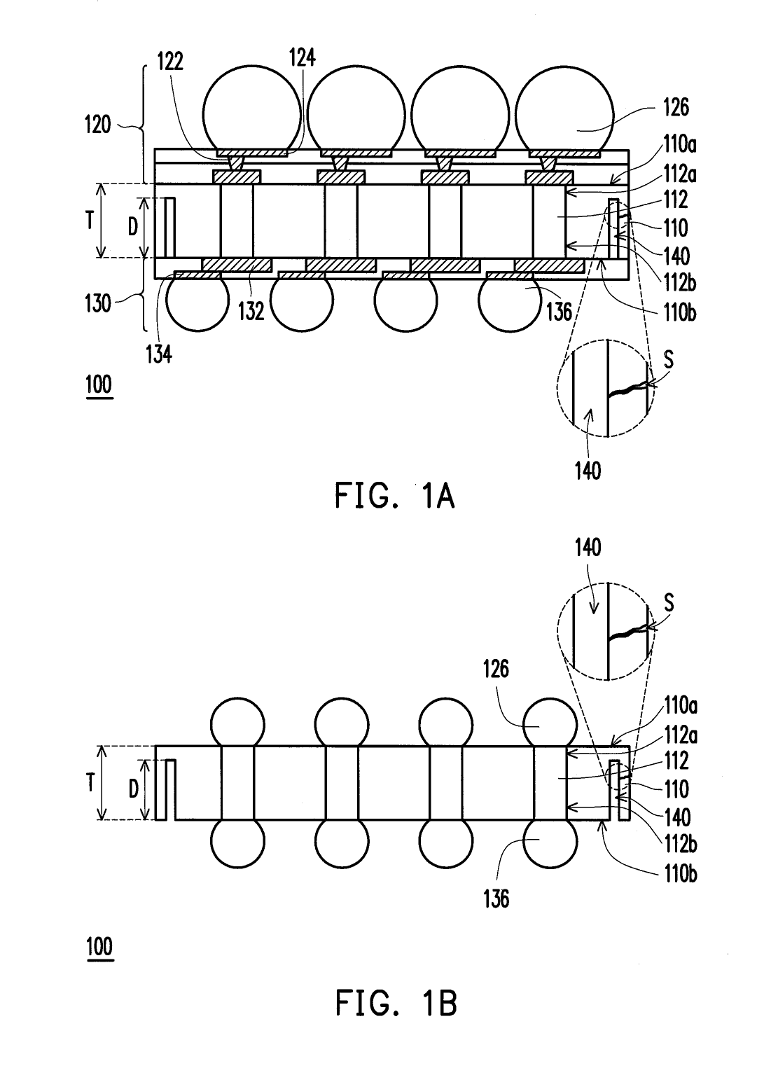

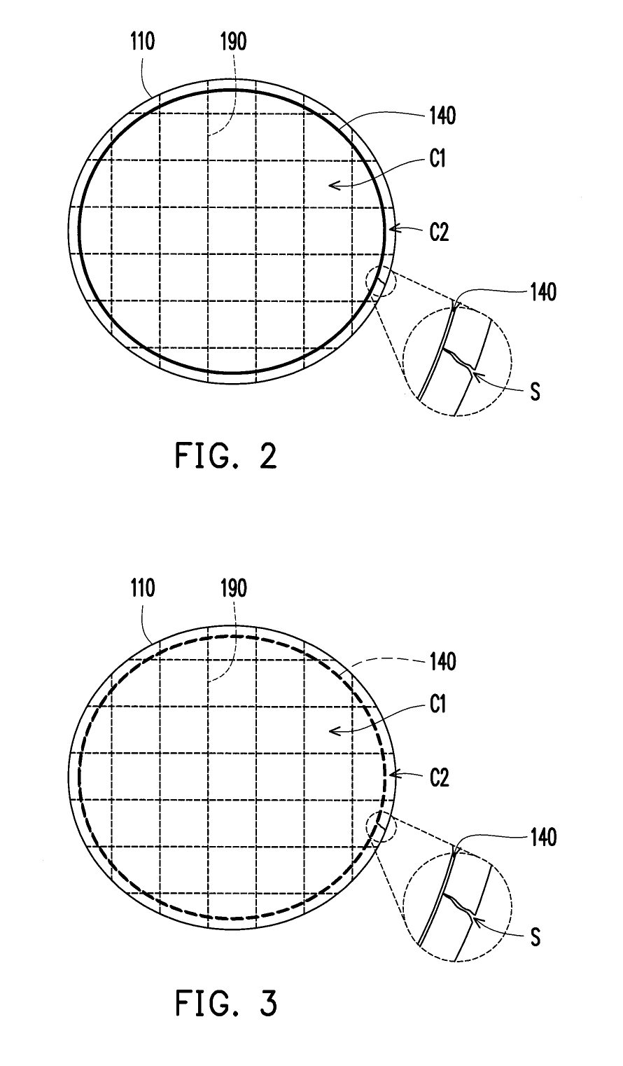

FIG. 1A is a schematic diagram illustrating a cross section of a semiconductor structure according to an embodiment of the disclosure. As shown in FIG. 1A, the semiconductor structure 100 comprises a semiconductor wafer 110, and the semiconductor wafer 110 has a plurality of TSVs 112 therein. In this embodiment, a first metalized structure 120 is arranged on a first surface 110a of the semiconductor wafer 110. The first metalized structure 120 herein may comprise a wiring layer and bumps located on the wiring layer. In this embodiment, the first metalized structure 120 comprises a first interconnection 122, a plurality of first bonding pads 124, and a plurality of first bumps 126, which is, for example, a wiring structure formed by a back end of line (BEOL) in a wafer process. The first interconnection 122 is, for example, connected between a first end 112a of each TSV 112 and the corresponding first bonding pad 124. The first bumps 126 are arranged on the corresponding first bonding pads 124. Other active or passive devices (not shown) may also exist in the semiconductor wafer 110, so the first interconnection 122 may also connect the active or passive devices. In addition, a second metalized structure 130 is arranged on a second surface 110b of the semiconductor wafer 110. The second metalized structure 130 may comprise a wiring layer and bumps located on the wiring layer. In this embodiment, the second metalized structure 130 comprises a second interconnection 132, a plurality of second bonding pads 134, and a plurality of second bumps 136. The second interconnection 132 is connected between a second end 112b of each of the TSVs 112 and the corresponding second bonding pad 134. The second bumps 136 are arranged on the corresponding second bonding pads 134.

In this embodiment, the semiconductor structure 100 having functionality is shown, and thus has the TSVs 112, the first interconnection 122, the first bonding pads 124, the second interconnection 132, the second bonding pads 134, and even active devices or passive devices. It is understood that in other embodiments of the disclosure, the semiconductor structure 100 may also be simply used as an interposer in a stack structure. FIG. 1B is a schematic diagram illustrating a cross section of a semiconductor structure according to an embodiment of the disclosure. Referring to FIG. 1B, it is necessary to form only the TSVs 112 in the semiconductor wafer 110, and the first bump 126 and the second bump 136 for external connection at two ends of each TSV 112, and it is unnecessary to form the first interconnection 122, the first bonding pads 124, the second interconnection 132, the second bonding pads 134, and active devices or passive devices on the semiconductor wafer 110.

It is understood that in the disclosure, the first interconnection 122, the first bonding pads 124, and the first bumps 126 as described above may be formed on the first surface 110a of the semiconductor wafer 110, and only the second bumps 136 connected to the TSVs 112 may be formed on the second surface 110b of the semiconductor wafer 110, or the second interconnection 132, the second bonding pads 134, and the second bumps 136 as described above may be formed on the second surface 110b of the semiconductor wafer 110, and only the first bumps 126 connected to the TSVs 112 may be formed on the first surface 110a of the semiconductor wafer 110.

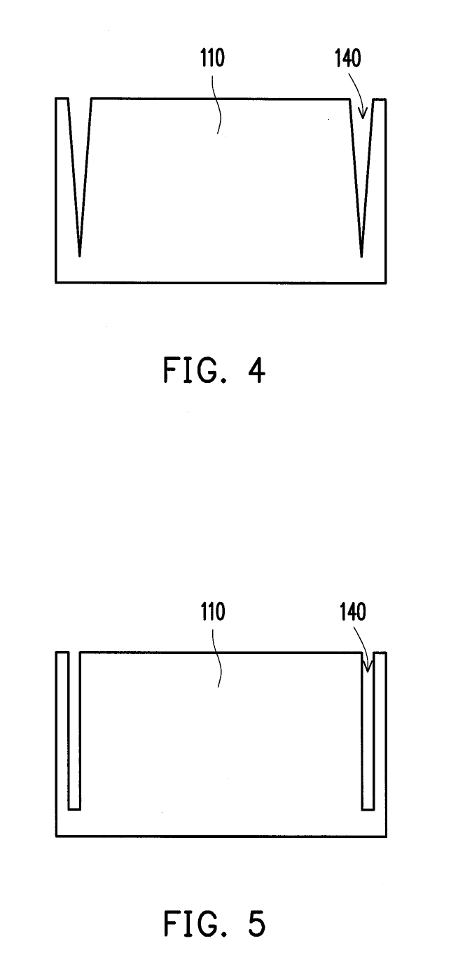

FIG. 2 is a schematic diagram illustrating a top view of the semiconductor structure in FIG. 1A or 1B. Referring to FIGS. 1A, 1B, and 2 at the same time, the semiconductor wafer 110 may be divided by a plurality of scribe lines 190 into a plurality of effective chip regions C1 and a plurality of incomplete ineffective chip regions C2 located on the edge of the semiconductor wafer 110. The effective chip regions C1 may become a plurality of independent chips after the semiconductor wafer 110 is cut, while the ineffective chip regions C2 are leftover materials after the semiconductor wafer 110 is cut, and may be discarded or recycled.

In this embodiment, to prevent the effective chip regions C1 of the semiconductor wafer 110 from being damaged by a crack S that may be produced at the edge of the thinned semiconductor wafer 110 due to the subsequent process like backside metalization, a crack stopping slot 140 is disposed in the periphery of the semiconductor wafer 110, to stop the crack S from extending to the effective chip regions C1 in the center of the semiconductor wafer 110. As can be known from the enlarged views in FIGS. 1A, 1B, and 2, the crack S is stopped upon meeting the crack stopping slot 140, and will no longer extend towards the center of the semiconductor wafer 110.

In order to maintain the layout space of the semiconductor wafer 110, in this embodiment, the crack stopping slot 140 is disposed in the ineffective chip regions C2 of the semiconductor wafer 110. In other words, the crack stopping slot 140 will be removed together with the leftover materials of the ineffective chip regions C2 after the semiconductor wafer 110 is cut. It is understood that in other embodiments of the disclosure, the crack stopping slot 140 may also be disposed at any possible location on the semiconductor wafer 110 according to requirements.

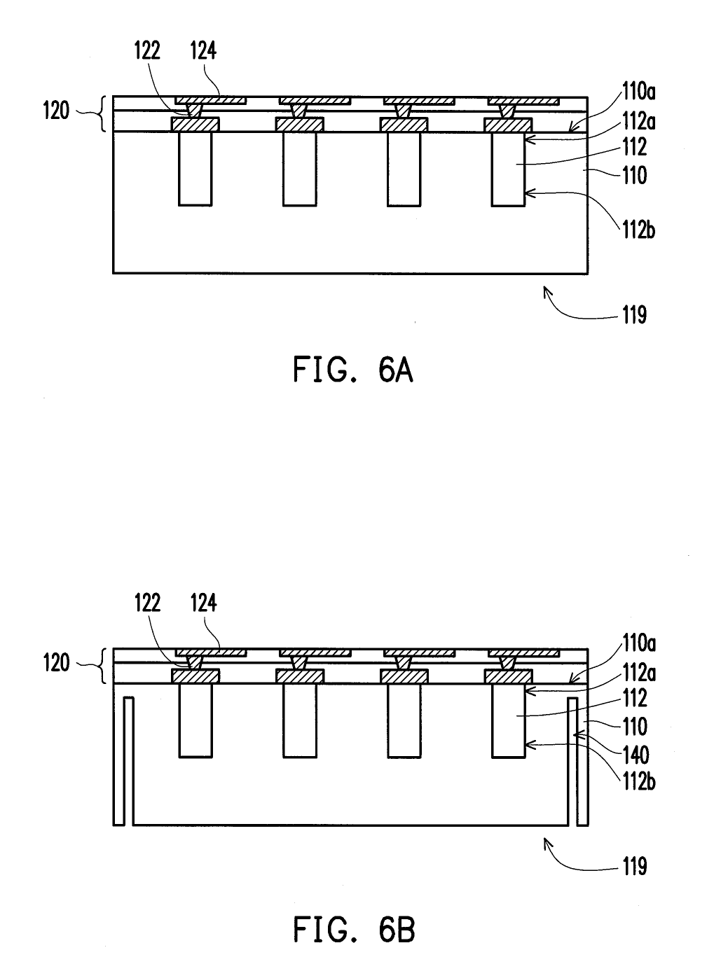

On the other hand, the crack stopping slot 140 formed in this embodiment is a structure formed by hollowing out the semiconductor wafer 110, for example, a continuous slot surrounding the semiconductor wafer 110 shown in FIG. 2. Or, in other embodiment, as shown in FIG. 3, the crack stopping slot 140 may also comprise a plurality of slots located in the periphery of the semiconductor wafer 110 and distributed discontinuously.

In this embodiment, a ratio of a depth D of the crack stopping slot 140 to a thickness T of the semiconductor wafer 110 is between 0.5 and 1. Herein, the thickness T of the semiconductor wafer 110 refers to the thickness of the thinned semiconductor wafer 110. Generally speaking, the thickness T may be between 5 and 200 Actually, the depth D of the crack stopping slot 140 should be large enough to stop the crack S, for example, is ½, ⅔, ¾, or ⅘ of the thickness T of the semiconductor wafer 110. The crack stopping slot 140 may even be deep enough to approach the first surface 110a of the semiconductor wafer 110. In other words, the ratio of the depth D of the crack stopping slot 140 to the thickness T of the semiconductor wafer 110 may be between 0.9 and 1.

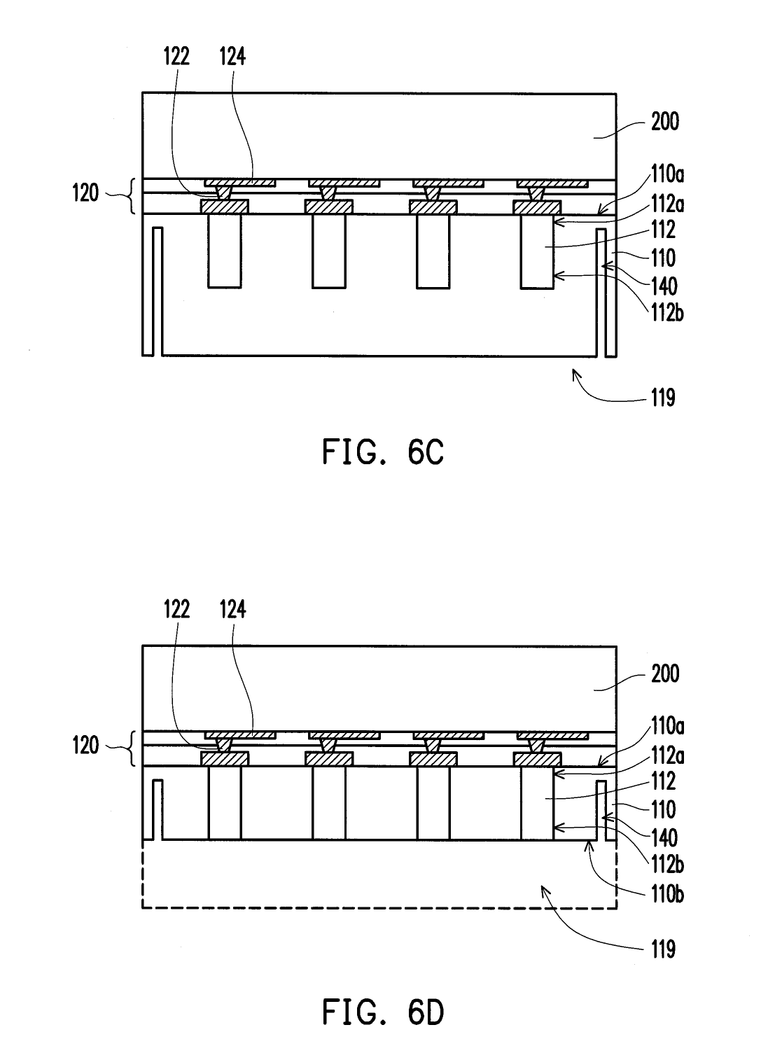

In addition, the crack stopping slot 140 in this embodiment may have different cross-sectional shapes. FIGS. 4 and 5 are respectively schematic diagrams illustrating cross-sectional structures of the crack stopping slot 140 in this embodiment. The crack stopping slot 140 shown in FIG. 4 is, for example, a V-shaped slot having a V-shaped cross section, and the crack stopping slot 140 shown in FIG. 5 is, for example, a U-shaped slot having a U-shaped cross section.

It is understood that the form of the crack stopping slot in the disclosure is not thus limited. The shape, depth, width, length, and location of the crack stopping slot may be different due to factors such as process conditions or design requirements. Those of ordinary skill in the art can form different types of crack stopping slots according o actual requirements, which will not be described herein again.

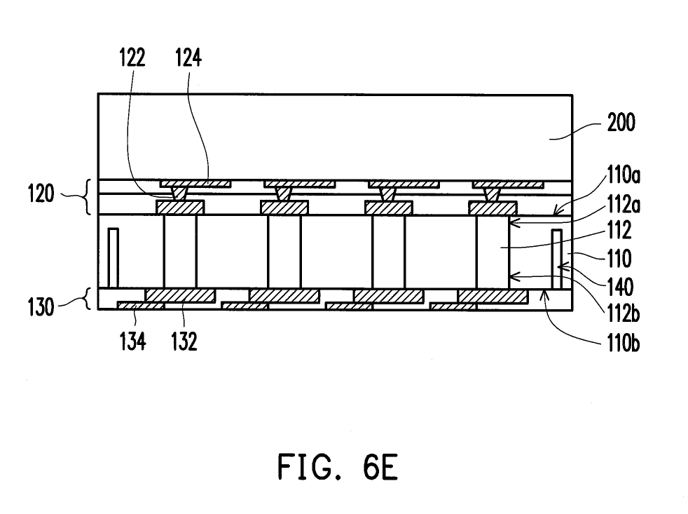

FIGS. 6A to 6E are schematic diagrams illustrating cross sections of a process of the semiconductor structure 100. Firstly, a semiconductor wafer 110 shown in FIG. 6A is provided. The semiconductor wafer 110 has TSVs 112 therein, a first end 112a of each TSV 112 is connected to a first surface 110a of the semiconductor wafer 110, and a second end 112b of each TSV 112 is embedded in the semiconductor wafer 110. A first metalization process may be performed on the first surface 110a of the semiconductor wafer 110, to form a first metalized structure 120, for example, a wiring structure formed by a BEOL in a wafer process, comprising an interconnection, bonding pads, and bumps that possibly exist (as shown in FIG. 1A).

It is understood that as described above, the semiconductor structure 100 may also be simply used as an interposer in a stack structure, in which it is necessary to form only the TSVs 112 in the semiconductor wafer 110, and it is unnecessary to form the interconnection, the bonding pads, or other active devices or passive devices on the semiconductor wafer 110.

Then, as shown in FIG. 6B, a crack stopping slot 140 is formed at a back side 119 of the semiconductor wafer 110 opposite to the first surface 110a. The crack stopping slot 140 is located in the periphery of the semiconductor wafer 110, and a depth of the crack stopping slot 140 is less than or equal to a thickness of the semiconductor wafer 110. A method for forming the crack stopping slot 140 is, for example, laser cutting or other applicable processing methods such as etching or mechanical cutting. Herein, the etching is, for example, dry etching.

Afterwards, as shown in FIG. 6C, for performing the subsequent thinning process conveniently, the semiconductor wafer 110 is bonded to a carrier 200. The carrier 200 is, for example, a carrying wafer. The first surface 110a of the semiconductor wafer 110 faces the carrier 200. In this embodiment, a first wiring layer 120 is formed on the first surface 110a of the semiconductor wafer 110, and thus the semiconductor wafer 110 is arranged on the carrier 200 with the first wiring layer 120 there-between.

Next, as shown in FIG. 6D, the semiconductor wafer 110 is thinned from the back side 119 of the semiconductor wafer 110 to expose the second end 112b of each TSV 112 and a second surface 110b of the semiconductor wafer 110. The thinning herein is to, for example, firstly perform coarse polishing with low precision till the second ends 112b of the TSVs 112 are approached and then perform chemical mechanical polishing (CMP) with high precision to expose the second ends 112b of the TSVs 112.

As shown in FIG. 2 or 3, since the crack stopping slot 140 is disposed in the periphery of the semiconductor wafer 110, a crack S produced at the edge of the thinned semiconductor wafer 110 may be stopped from extending towards effective chip regions C1 in the center of the semiconductor wafer 110, to prevent the effective chip regions C1 from being damaged by the crack S.

Afterwards, in this embodiment, optionally, as shown in FIG. 6E, a second metalization process is performed on the second surface 110b of the semiconductor wafer 110, to form a second metalized structure 130 to serve as a bridge for connecting the semiconductor wafer 110 to other devices. Moreover, the semiconductor wafer 110 is separated from the carrier 200, to obtain the semiconductor structure 100 shown in FIG. 1A or 1B. The second metalized structure 130 herein, as described in the above embodiments, may comprise an interconnection, bonding pads, and bumps that possibly exist (as shown in FIG. 1A), or as shown in FIG. 1B, the interconnection and the bonding pads may be omitted, and only the bumps connected to the TSVs 112 are formed.

Based on the above, in the disclosure, a crack stopping slot is disposed in the periphery of a semiconductor wafer, so that even if a crack may be produced at a sharp edge of the semiconductor wafer after the semiconductor wafer is thinned, the crack stopping slot can effectively stop the crack from extending towards the center of the semiconductor wafer, thus preventing effective chip regions in the center of the semiconductor wafer from being damaged by the crack. Therefore, the semiconductor structure and process provided in the disclosure can have desirable process yield and throughput.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. A semiconductor structure, comprising:
a semiconductor wafer, provided with a first surface and a second surface opposite to the first surface;
a plurality of through silicon vias (TSVs), embedded in the semiconductor wafer, wherein a first end of each TSV is connected to the first surface, and a second end of each TSV is connected to the second surface; and
a crack stopping slot, located in the periphery of the second surface of the semiconductor wafer, wherein a depth of the crack stopping slot is less than or equal to a thickness of the semiconductor wafer.

2. The semiconductor structure according to claim 1, wherein the crack stopping slot is a continuous slot surrounding the semiconductor wafer.

3. The semiconductor structure according to claim 1, wherein the crack stopping slot comprises a plurality of slots located in the periphery of the semiconductor wafer and distributed discontinuously.

4. The semiconductor structure according to claim 1, further comprising a first metalized structure arranged on the first surface of the semiconductor wafer.

5. The semiconductor structure according to claim 1, further comprising a second metalized structure arranged on the second surface of the semiconductor wafer.

6. The semiconductor structure according to claim 1, wherein the semiconductor wafer comprises a plurality of complete effective chip regions and a plurality of incomplete ineffective chip regions located on an edge of the semiconductor wafer, and the crack stopping slot is located in the ineffective chip regions.

7. The semiconductor structure according to claim 1, wherein the crack stopping slot is a U-shaped slot or a V-shaped slot.

8. The semiconductor structure according to claim 1, wherein the crack stopping slot is hollowed out.

9. The semiconductor structure according to claim 1, wherein a ratio of the depth of the crack stopping slot to the thickness of the semiconductor wafer is between 0.5 and 1.

10. The semiconductor structure according to claim 9, wherein the ratio of the depth of the crack stopping slot to the thickness of the semiconductor wafer is between 0.9 and 1.

11. A semiconductor process, comprising:
providing a semiconductor wafer, wherein the semiconductor wafer is provided with a first surface, the semiconductor wafer is provided with a plurality of through silicon vias (TSVs) therein, and a first end of each TSV is connected to the first surface;
forming a crack stopping slot at a back side of the semiconductor wafer opposite to the first surface, wherein the crack stopping slot is located in the periphery of the semiconductor wafer, and a depth of the crack stopping slot is less than or equal to a thickness of the semiconductor wafer; and
thinning the semiconductor wafer from the back side to expose a second end of each TSV and a second surface of the semiconductor wafer.

12. The semiconductor process according to claim 11, wherein the crack stopping slot is a continuous slot surrounding the semiconductor wafer.

13. The semiconductor process according to claim 11, wherein the crack stopping slot comprises a plurality of slots located in the periphery of the semiconductor wafer and distributed discontinuously.

14. The semiconductor process according to claim 11, further comprising performing a first metalization process on the first surface of the semiconductor wafer.

15. The semiconductor process according to claim 11, further comprising performing a second metalization process on the second surface of the semiconductor wafer.

16. The semiconductor process according to claim 11, wherein the semiconductor wafer comprises a plurality of complete effective chip regions and a plurality of incomplete ineffective chip regions located on an edge of the semiconductor wafer, and the crack stopping slot is located in the ineffective chip regions.

17. The semiconductor process according to claim 11, wherein the crack stopping slot is hollowed out.

18. The semiconductor process according to claim 11, wherein a ratio of the depth of the crack stopping slot to a thickness of the thinned semiconductor wafer is between 0.5 and 1.

19. The semiconductor process according to claim 18, wherein the ratio of the depth of the crack stopping slot to the thickness of the semiconductor wafer is between 0.9 and 1.

20. The semiconductor process according to claim 11, wherein a method for forming the crack stopping slot comprises laser cutting, mechanical cutting, or etching.
